(19) United States
(12) Patent Application Publication
(10) Pub. No.: US 2017/0021319 A1
(43) Pub. Date: Jan. 26, 2017

(54) HYDROCHLORINATION REACTOR

(71) Applicant: SITEC GMBH, Augsburg (DE)

(72) Inventors: Mark William Dassel, Poulsbo, WA (US); Michael VanDeVanter, Poulsbo, WA (US)

(73) Assignee: SiTec GmbH, Augsburg (DE)

(21) Appl. No.: 15/124,343

(22) PCT Filed: Mar. 10, 2015
(86) PCT No.: PCT/US2015/019793

§ 371 Date: Sep. 7, 2016

Related U.S. Application Data
(60) Provisional application No. 61/950,794, filed on Mar. 10, 2014.

(51) Int. Cl. B01J 7/00; B01J 19/02; C23C 16/448; C01B 33/035; C23C 16/24; B01J 19/24; C01B 33/107

(52) U.S. Cl. CPC B01J 7/00; B01J 19/244; B01J 19/02; C01B 33/10763; C01B 33/035; C23C 16/24; C23C 16/4488; B01J 2219/0277

(57) ABSTRACT

Improved hydrochlorination reactors, which have a larger internal volume and hence functional capacity than presently available hydrochlorination reactors, may be prepared with reactor walls having inner and outer layers where each layer provides a unique benefit, the inner layer having hydrogen chloride resistance and the outer layer having high strength at elevated temperature and pressure. Alternatively, or additionally, hoops may be disposed along the outside of the reactor wall to provide additional strength to the reactor during operation. Specified materials may be used to form the reactor wall in order to provide both acid resistance and high strength at elevated operating temperatures.

### CROSS-REFERENCE TO RELATED APPLICATION

This application claims the benefit under 35 U.S.C. §119(e) of U.S. Provisional Patent Application No. 61/950,794 filed Mar. 10, 2014, which application is incorporated herein by reference in its entirety.

### FIELD OF THE INVENTION

The present invention relates generally to chemical reactors, and more specifically to an improved design for a reactor useful in performing hydrochlorination chemistry.

### BACKGROUND

Technical Field

The present invention relates to the field of polysilicon production, and in particular to a design suitable for a hydrochlorination reactor, i.e., a reactor wherein a hydrochlorination reaction takes place in conjunction with polysilicon production, for example by the Siemens process.

Description of the Related Art

In hydrochlorination, silicon tetrachloride (STC) is reacted with hydrogen and metallurgic silicon (MGSi) to produce trichlorosilane (TCS) according to the chemical reaction:

3 STC+2 H₂+1 MGSi→4 TCS

Hydrochlorination typically takes place in fluid bed reactors operating at, for example, 33 barg and a temperature of from 550° C. to 600° C. The reaction is catalyzed by molecular species comprising copper trichloride, and typically proceeds to equilibrium.

There are various problems associated with this hydrochlorination process. Some of these problems are associated with the very high operating temperature required for hydrochlorination (500° C. to 600° C.). This high operating temperature contributes to the need to run the fluid bed reactor at relatively high pressure (e.g., 33 barg). High pressure is required to compress the gas in the reactor such that the required hold up time for the reaction can be achieved in a reasonably sized reactor. Reactors that operate at high temperature and high pressure are relatively expensive to build, run and maintain. For example, such reactors may require expensive alloys (e.g., INCOLOY 800H) in order to achieve high strength at high temperatures, which drives up plant capital cost. In order to run such reactors efficiently, it is typically necessary to install electrically heated equipment to superheat hydrogen and STC feed gases to the hydrochlorination reactor operating temperature. This, of course, increases the capital equipment and operating cost for a plant that utilizes this process. In addition, such reactors have inherent safety hazards, which are significant. A major release of hydrochlorination reactor content could have catastrophic effects on plant personnel and the surrounding community, resulting in loss of life and extensive destruction of capital equipment.

Another problem with hydrochlorination is the low conversion per pass across the hydrochlorination reactor. Typically only 20% to 40% of the STC fed is converted to TCS. The low conversion per pass across the hydrochlorination reactor results in the generation of large STC recycle streams, with concomitant expense in capital equipment and plant operating cost.

Yet another problem associated with the use of hydrochlorination is that the relocation of the STC recovery process from the back-end of the plant (i.e., the “clean end” of the plant downstream of the CVD reactors) to the front-end of the plant (i.e., the “dirty end” of the plant in the fluid bed reactors) means that the intervening TCS purification processes (purification is substantially performed in large distillation columns) must be sized as much as 4X larger than those required for alternative processes, e.g., direct chlorination.

The present invention is directed to solving problems associated with hydrochlorination and in particular to addressing shortcomings with hydrochlorination reactors.

### SUMMARY OF THE INVENTION

Briefly stated, the present disclosure provides for large hydrochlorination reactors. The reactors of the present disclosure can operate under hydrochlorination conditions of equal to or greater than 500° C. and equal to or greater than 30 barg. In one aspect, the present disclosure provides a multi-layer reactor design including a method of preparing and operating the multi-layer reactor and incorporating the multi-layer reactor into a chemical plant for producing polysilicon.

For example, the present disclosure provides the following exemplary embodiments:
1) A reactor for hydrochlorination, comprising a reactor shell in the form of a cylinder, the shell comprising an inner layer in contact with the contents of the reactor, and an outer layer that is adjacent to and in contact with the inner layer but is not in contact with the contents of the reactor, the inner layer comprising a first material having hydrochloric acid resistance and optionally having hydrochloride resistance which is greater than or is equal to the hydrochloride resistance of the outer layer, and the outer layer comprising a second material having a tensile strength that is greater than or is equal to, or is higher than, the tensile strength of the first material.
2) The reactor of embodiment 1 wherein the first material is selected from INCOLOY 800H alloy and tantalum.
3) The reactor of embodiment 1 or 2 wherein the second material is selected from INCOLOY 800 H alloy or functional equivalent alloy, RA253MA steel or functional equivalent steel and Haynes HR-120 alloy or functional equivalent alloy, or stainless steel such as 347 stainless steel and 321 stainless steel.
4) A reactor for hydrochlorination comprising a reactor shell in the form of a cylinder having an interior and an inner diameter and an exterior and an outer diameter and a longitudinal axis, and a plurality of hoops disposed along the longitudinal axis, each hoop encircling the exterior of the reactor shell and being adjacent to and in contact with the exterior of the reactor shell when the reactor is operating at elevating temperature and pressure.
5) The reactor of embodiment 4 wherein a hoop is 3-5 inches thick and 12-24 inches deep.
6) A reactor for hydrochlorination that comprises an interior, an exterior, and a reactor shell that separates the interior from the exterior, the reactor shell comprising HR120 steel or equivalent such that HR120 steel or equivalent contacts both the interior and the exterior of the reactor.
7) The reactor of any one of embodiments 1-6 comprising a cylindrical design, the cylinder having an inside diameter as measured by the distance between opposing inner walls of the shell, the inner diameter being in excess of 3 meters.
8) The reactor of embodiment 7 wherein the reactor shell comprises at least an inner layer in contact with the contents of the reactor and an outer layer that is in contact with the inner layer but is not in contact with the contents of the reactor, each of the inner and outer layers having a thickness independently selected from the range of 1.5 to 5.0 inches, or from the range of 1.5 to 3.5 inches.
9) The reactor of embodiment 7 wherein the reactor shell has a thickness of greater than 3.5 inches.
10) A reactor for conducting a hydrochlorination reaction, the reactor comprising a reactor shell, the reactor shell being a multi-layer construct comprising:
   a) a first layer in contact with an internal cavity of the reactor, the first layer having a nickel content of at least 25 wt % and a chromium content of at least 17 wt % so as to have hydrochloric acid corrosion resistance;
   b) a second layer in contact with the first layer and not in contact with the internal cavity, the second layer having a tensile strength of at least 9,000 psi at 1100° F.
11) The reactor of embodiment 10 wherein the internal cavity has a minimum diameter of 8-20 feet, or from 10-20 feet.
12) The reactor of embodiment 10 wherein each of the first layer and the second layer has a thickness independently selected from the range of from 0.25-5 inches, or from 0.25-3 inches.
13) The reactor of embodiment 10 wherein each of the first layer and the second layer has a thickness independently selected from the range of from 1.5-5 inches, or from 0.25-3 inches.
14) The reactor of embodiment 10 wherein the first and second layers are made from materials having different chemical composition.
15) The reactor of embodiment 10 wherein the first and second layers are made from materials having identical chemical composition.
16) The reactor of embodiment 10 wherein the reactor wall further comprises a third layer in contact with the second layer, the third layer not in contact with the first layer.
17) The reactor of embodiment 10 wherein the second layer entirely encompasses the first layer.

Also, for example, the present disclosure provides the following exemplary embodiments for operating a multi-layer reactor:
18) A chemical plant comprising a reactor of any of embodiments 1-17 and a chemical vapor deposition reactor for the production of polysilicon.
19) A process for hydrochlorination comprising:
   a) providing a hydrochlorination reactor operating at a temperature in excess of 500° C. and optionally operating at a pressure in excess of 30 barg (435 Psig), the reactor having an inside diameter of between 8 and 20 feet, or of between 10 and 20 feet;
   b) introducing silicon tetrachloride, hydrogen (H₂) and metallurgical silicon into the hydrochlorination reactor; and
   c) collecting trichlorosilane from the hydrochlorination reactor.

Furthermore, the present disclosure provides methods for preparing multi-layer reactors, including the following exemplary embodiment:
20) A process for manufacturing a reactor for conducting a hydrochlorination reaction, the reactor comprising a reactor shell, the reactor shell being a multi-layer construct comprising a first layer in contact with an internal cavity of the reactor and a second layer in contact with the first layer and not in contact with the internal cavity, the process comprising
   a) providing a reactor inner layer having an inner diameter and an outer diameter;
   b) providing a reactor outer layer having an inner diameter and an outer diameter, where the outer diameter of the inner layer is greater than the inner diameter of the outer layer at room temperature of about 25° C.;
   c) heating the outer layer to provide an expanded outer layer, where the expanded outer layer has an inner diameter which is larger than the outer diameter of the inner layer;
   d) inserting the inner layer into the expanded outer layer, or slipping the expanded outer layer over the inner layer; and
   e) cooling the expanded outer layer to the same temperature of the inner layer to provide a wall of a reactor.

### DESCRIPTION OF THE INVENTION

The present invention relates to the field of polysilicon production, and in particular to a design suitable for a hydrochlorination reactor, i.e., a reactor wherein a hydrochlorination reaction takes place. The hydrochlorination may take place in conjunction with polysilicon production, for example by the Siemens process. The reactor may also be used to make silane that is converted into polysilicon for flat panel displays and specialty microelectronics.

Improved hydrochlorination reactors, which have a larger internal volume and hence functional capacity than presently available hydrochlorination reactors, may be prepared having a multi-layer construction, i.e., with reactor walls having 2 or more layers such as an inner layer and an outer layer (cladding and backing, respectively) where each layer may provide a unique benefit; for example, the cladding having hydrogen chloride resistance and the backing having high strength at elevated temperature and pressure. The layers of a multi-layer reactor as disclosed herein are physically distinct from one another, although as described in more detail below, they are positioned directly adjacent to one another without any intervening gap. Alternatively, or additionally, hoops may be disposed along the outside of the reactor wall to provide additional strength to the reactor during operation. Specified materials may be used to form the reactor wall in order to provide both acid resistance and high strength at elevated operating temperatures.

Hydrochlorination reactors require reactors walls that provide both corrosion resistance and high strength at operating conditions of high temperature (over 500° C.) and high pressure (over 30 barg). In order to provide the necessary strength under these operating conditions when a reactor inner diameter exceeds about 8 feet, the thickness of the reactor wall must exceed about 3 inches. However, nickel alloy sheet such as INCOLOY 800H sheet of greater than about 3 to 3.5 inches in thickness is not recognized as safe for high temperature and pressure applications in view of the inherent properties of the metal, e.g., the desired and necessary grain structure of the metal deteriorates as the sheet thickness exceeds about 3.5 inches. In one embodiment the present invention provides a reactor construction that is suitable for large diameter hydrochlorination reactors, and makes use of metal sheet that has a thickness of less than 5 inches, or less than 4.5 inches, or less than 4.0 inches, or less than 3.5 inches, or less than 3.0 inches. In brief, the present disclosure provides a reactor wall formed from two or more layers, i.e., a multi-layer wall, each layer in very close proximity to another layer, with the one layer backing up an adjacent layer so that together they provides the required strength for the reactor wall, without exceeding the maximum thickness that is recognized as being safe for each layer.

In one aspect, the present invention provides a reactor for hydrochlorination. The reactor comprises a reactor shell at least partially in the form of a cylinder, the inner layer of the reactor shell comprising a first material having hydrochloric acid resistance which is equal to or greater than the hydrochloride resistance of the outer layer, and the outer layer comprising a second material having tensile strength which is equal to or greater than the tensile strength of the first material. The reactor shell is thus in the form of a bilayer, where the inner layer provides good chemical resistance and some mechanical strength but not adequate mechanical strength to maintain the reactor integrity at elevated temperature and pressure absent the presence of the outer layer, and the outer layer provides adequate mechanical strength and may or may not provide adequate chemical resistance for operation under hydrochlorination conditions. Since the outer layer does not come into contact with the contents of the reactor, the chemical resistance of the outer layer is not important, and the material(s) which form the outer layer may be selected primarily on the basis of mechanical strength of the material and its thermal properties vis-à-vis the inner layer. The inner and outer layers should have similar or identical thermal expansion properties so that, as the reactor is heated and cooled, the inner and outer layers remain in contact with one another.

The inner layer, which may also be called the reactor liner or the cladding, needs to have hydrochloric acid resistance because hydrochlorination reactors typically receive and generate hydrochloric acid, and the internal cavity of the reactor is exposed to this hydrochloric acid. Hydrochloric acid vapor is corrosive, particularly at temperatures in the range of 400-800° C., which is the range of typical operating temperatures for a hydrochlorination reactor. The inner layer is preferably metallic, which includes metal alloys. Suitable materials for forming the inner layer include INCOLOY™ alloys from Special Metals Corporation, which are designed for excellent corrosion resistance as well as strength at high temperatures. A suitable INCOLOY alloy is selected from the INCOLOY 800 series of alloys, including INCOLOY 800H alloy. Information describing INCOLOY alloy 800 is available in Special Metals publication SMC-045. Other suitable metals include tantalum and stainless steel including 347 stainless steel and 321 stainless steel. Suitable materials also include functional equivalents of INCOLOY 800H alloy, functional equivalents of tantalum, and functional equivalents of stainless steel such as 347 stainless steel and 321 stainless steel.

In one embodiment, the material from which the inner layer is made comprises both nickel and chromium, and optionally iron. In various embodiments, desired hydrochloric acid corrosion resistance may be achieved when the nickel content of the inner layer is at least 23 wt %, or at least 24 wt %, or at least 25 wt %, or at least 26 wt %, or at least 27 wt %, or at least 28 wt %, or at least 29 wt %, or at least 30 wt %, or at least 31 wt %, or at least 32 wt %, or at least 33 wt %, or at least 34 wt %, or at least 35 wt %. In addition, or alternatively, desired hydrochloric acid corrosion resistance may be achieved when the chromium content is at least 15 wt %, or at least 16 wt %, or at least 17 wt %, or at least 18 wt %, or at least 19 wt %, or at least 20 wt %, or at least 21 wt %, or at least 22 wt %, or at least 23 wt %, or at least 24 wt %, or at least 25 wt %. Suitable alloys meeting these specification are available, for example, in the INCOLOY line of alloys from Special Metals Corporation (New Hartford, N.Y.).

The outer layer needs to have high tensile strength. In large part, the outer layer provides the mechanical strength of the reactor, which allows it to contain gas at a high operating pressure of about 33 barg, or greater than 30 barg (435 Psig). The outer layer needs to provide high mechanical strength, e.g., tensile strength, since the inner layer is required primarily to be resistant to hydrochloric acid rather than imparting strength to the reactor. An important consideration is that both the inner and outer layers of the reactor will reach a temperature of about 600° C. during reactor operation, and the outer layer in particular needs to have excellent mechanical (e.g., tensile) strength) at this high temperature.

Accordingly, the tensile strength at elevated temperature is in important criteria in selecting the material from which to form the outer layer of a bilayer reactor. Tensile strength may be expressed using various units, including units of KSI, which refers to kilo-pounds per square inch. In various embodiments, the outer layer has a tensile strength, in units of KSI, as measured at 1100F (593° C.), of at least 3.0, or at least 3.5, or at least 4.0, or at least 4.5, or at least 5.0, or at least 6.0, or at least 6.5, or at least 7.0, or at least 7.5, or at least 8.0, or at least 8.5, or at least 9.0, or at least 9.5, or at least 10.0, or at least 10.5, or at least 11.0, or at least 11.5, or at least 12.0 In addition, or alternatively, the outer layer may optionally have a tensile strength, in units of KSI, as measured at 1150F (621° C.), of at least 2.0, or at least 2.5, or at least 3.0, or at least 3.5, or at least 4.0, or at least 4.5, or at least 5.0, or at least 5.5, or at least 6.0, or at least 6.5, or at least 7.0, or at least 7.5, or at least 8.0, or at least 8.5, or at least 9.0, or at least 9.5, or at least 10.0. In one embodiment, the tensile strength of the outer layer is at least 9 Ksi at 1100 F, or at least 9.5 Ksi at 1100 F, or at least 10 Ksi at 1100 F.

The outer layer of a bilayer reactor is preferably metallic, which includes metal alloys. Suitable materials for forming the outer layer include: RA253MA steel (Rolled Alloys, Inc., Temperance, Mich.) and Haynes HR-120 alloy (Haynes International Inc., Kokomo, Ind., USA). HR-120 is a metal alloy containing 33Fe^{a}-37Ni-25Cr-3Co*-2.5Mo*-2.5W*-0.7Cb-0.7Mn-0.6Si-0.20N-0.1Al-0.05C-0.0048 (^{a} as balance; * Maximum). The outer layer may be a functional equivalent of HR-120. RA253MA is also a metal alloy, where RA253MA contains Cr(20-22)-Ni(10-12)-Si(1.4-2.0)-C(0.05-0.1)-Mn(under 0.8)-P(under 0.04)-S(under 0.03)-N(0.2-0.14)-Ce(0.08-0.03) and the balance is iron (Fe). The outer layer may be made from a functional equivalent of RA253MA. Other suitable metallic materials include stainless steel, carbon steel and INCOLOY steel. Suitable alloys meeting the tensile strength specifications as set forth above are available, for example, in the INCOLOY line of alloys from Special Metals Corporation (New Hartford, N.Y.).

The liner and casing are adjacent to one another, preferably with no gap or space between them. When the multi-layer reactor has more than 2 layers, then each of the layers is preferably in contact with the adjacent layer(s) with no gaps being present between any two layers. A cladding process, e.g., by fusion welding or friction welding, may be used to place adjacent layers, e.g., the two layers of a bilayer reactor shell, into intimate proximity. An exemplary fusion welding process is explosive welding (or cladding), which is also known as explosion welding or explosive bonding. It is the bonding of two or more similar or dissimilar metals with the aid of explosives and is accomplished by a high-velocity oblique impact between two metals. The impact produces sufficient energy to cause the colliding metal surfaces to flow hydrodynamically when they intimately contact one another in order to promote solid-state bonding. The metal surfaces are compressed together under high pressure from the explosion, and an atomistic bonding between the dissimilar metals will be accomplished. Explosive cladding is a cold pressure weld process (at room temperature). It is a method to weld metals together.

The explosion bonding process is based on utilizing the impulse from the running detonation of a high explosive to accelerate a metal cladding component to a high velocity. The cladding component, after moving across a standoff gap or separation distance, collides with a stationary metal base component. The collision is characterized by the velocity of the cladding component and the angle of collision between the two components. When these conditions are within certain well defined limits, as dictated by the metals or alloys being bonded, flow and hydrodynamic jetting of the surface layers of the two metals occur and the metals are welded or bonded together. The jet serves as the mechanism to clean away all oxides, absorbed gases and other surface contaminants. Due to the angled collision, this high velocity stream of material (jet) which is expelled from the collision zone leaving behind uncontaminated metal surfaces in intimate contact for the metallurgical bond to occur. When proper welding conditions are employed, the residual heat generated by the process is negligible thus giving it the capability of bonding a wide variety of dissimilar metals combinations.

In another option, two shells (also referred to herein as layers) of suitable size, i.e., of suitable thickness and diameter, are prepared and then combined. For example, the outer one is slipped over the inner one. Optionally, the outer one may be heated so that it expands, while the inner shell is maintained at room temperature. The heated outer shell is then slipped over the (not heated) inner shell, so that upon cooling the outer shell contracts and fits very tightly against the inner shell. In this way, no gap is present between the inner and outer shells that form the wall of the reactor. This process may be repeated to add a third layer to the reactor wall, i.e., to prepare a tri-layer reactor or other multi-layer reactor.

Thus, the present disclosure provides a method for preparing a large hydrochlorination reactor as disclosed herein. The method includes preparing two shells which when combined together will form the inner and outer layers of a bilayer reactor wall. Each of the inner and outer layers may have properties, e.g., dimensions and compositions, as described herein. At room temperature, the inner diameter of the outer layer is slightly smaller than, or it is essentially the same size as, the outer diameter of the inner layer. At room temperature, the inner layer is so large that it will not slip into the inside diameter of the outer layer. However, when the outer layer is heated, the outer layer will expand such that it's inner diameter increases and becomes larger than the outer diameter of the inner layer as measured at room temperature. This (relatively cool) inner layer may then be slid into the (relative hot, expanded) outer layer. After the inner layer is positioned within the outer layer, the outer layer is allowed to cool to the same temperature as the inner layer. This cooling will cause contraction of the outer layer and thereby provide a very tight fit between the inner and outer layers, such that there is no gap between the two layers.

The reactor will have a top wall and a bottom wall in addition to a side wall. The side wall is typically in a cylindrical shape. The top and/or bottom wall may be flat, or one or both of the top and bottom walls may be curved or hemispherical in shape. In preparing a reactor of the present disclosure, the bilayer side wall may be constructed, and then the top and bottom walls may be welded onto the bilayer side wall. The top and bottom walls will have a bilayer construction to match the bilayer construction of the side wall. Optionally, after the bilayer sidewall has been constructed, the inner layer of the top wall and the inner layer of the bottom wall are welded to the inner layer of the side wall. Then, the outer layer of the bottom wall and the outer layer of the top wall are welded to the outer layer of the side wall. While the inner layer of the top or bottom wall must be welded into place before an outer layer of the top or bottom wall may be welded into place, the top wall may be welded into place before the bottom wall, or the bottom wall may be welded into place before the top wall.

Optionally, the inner layer of the top wall and/or the inner layer of the bottom wall may be welded onto the inner layer of the side wall prior to the inner layer being inserted into the outer layer. Also optionally, one (although not both) of the outer layer of the top wall and the outer layer of the bottom wall may be welded onto the outer layer of the side wall prior to the inner side wall layer being inserted into the outer side wall layer.

In one embodiment, there is provided a method of preparing a wall of a bilayer reactor, the method comprising (a) providing a reactor inner layer having an inner diameter and an outer diameter; (b) providing a reactor outer layer having an inner diameter and an outer diameter, where the outer diameter of the inner layer is greater than the inner diameter of the outer layer at room temperature of about 25° C.; (c) heating the outer layer to provide an expanded outer layer, where the expanded outer layer has an inner diameter which is larger than the outer diameter of the inner layer; (d) inserting the inner layer into the expanded outer layer, or slipping the expanded outer layer over the inner layer; (e) cooling the expanded outer layer to the same temperature of the inner layer to provide a wall of a reactor. Optionally, the inner layer may be heated to a temperature greater than room temperature, but is not heated so hot that it expands to have an outer diameter that is greater than the inner diameter of the expanded outer layer. Optionally, the inner and outer layers are made from the same material. Optionally, and as measured at room temperature, each of the inner and outer layers has a thickness independently selected from 1-5.0 inches, or 1.5-4.5 inches, or 1.5-4.0 inches, or 1.5-3.5 inches, or 1.5-3.0 inches. Optionally, the inner layer includes a side wall inner layer and one or both of a top wall inner layer and a bottom wall inner layer. Also optionally, the outer layer includes one but not both of a top wall outer layer and a bottom wall outer layer, in addition to the side wall outer layer. Optionally, the reactor wall is formed from two layers of INCOLOY 800 H, each layer being 3.5 inches in thickness with the outer layer being slipped over the inner layer.

The reactors of the present invention, which have both a liner (inner layer) and a backing material (outer layer), may have a minimum wall thickness of at least 2.0, or at least 2.5, or at least 3.0, or at least 3.5, or at least 4.0, or at least 4.5, or at least 5.0, or at least 5.5, or at least 6.0, or at least 6.5, or at least 7.0, or at least 7.5, or at least 8.0, or at least 8.5, or at least 9.0, or at least 9.5 or at least 10.0 inches. The wall thickness may also be expressed as a maximum thickness, where the maximum wall thickness is not more than 18.0 inches, or not more than 17.5 inches, or not more than 17.0 inches, or not more than 16.5 inches, or not more than 16.0 inches, or not more than 15.5 inches, or not more than 15.0 inches, or not more than 14.5 inches, or not more than 14.0 inches, or not more than 13.5 inches, or not more than 13.0 inches, or not more than 12.5 inches, or not more than 12.0 inches, or not more than 11.5 inches, or not more than 11.0 inches, or not more than 10.5 inches, or not more than 10.0 inches, or not more than 9.5 inches, or not more than 9.0 inches, or not more than 8.5 inches, or not more than 8.0 inches, or not more than 7.5 inches, or not more than 7.0 inches, or not more than 6.5 inches, or not more than 6.0 inches, or not more than 5.5 inches, or not more than 5.0 inches, or not more than 4.5 inches, or not more than 4.0 inches. The present disclosure provides a range of distance within which the thickness of the wall falls, where that range may be expressed by selecting any of the minimum distances set forth above in combination with any of the maximum distances set forth above, with the maximum distance of course being greater than the minimum distance.

In one embodiment, the liner (inner layer) has a thickness which is less than the thickness of the backing (outer layer). The liner may have a minimum thickness of at least ¼ inch, or ½ inches, or ¾ inch, or 1 inch, or 1¼ inch, or 1½ inch, or 1¾ inch, or 2 inches, or 2¼ inch, or 2½ inch, or 2¾ inch or 3 inches, or 3¼ inch, or 3½ inch, or 3¾ inch or 4 inches. Likewise, the thickness of the liner may be expressed in terms of its maximum thickness, where that maximum thickness if less than 7 inches, or less than 6¾ inches, or less than 6½ inches, or less than 6¼ inches, or less than 6 inches, or less than 5¾ inches, or less than 5½ inches, or less than 5¼ inches, or less than 4 inches, or less than 3¾ inches, or less than 3½ inches, or less than 3¼ inches, or less than 3 inches, or less than 2¾ inches, or less than 2½ inches, or less than 2¼ inches, or less than 2 inches, or less than 1¾ inches, or less than 1½ inches, or less than 1¼ inches, or less than 1 inch, or less than ¾ inch, or less than ½ inch. The present disclosure provides a range of distance within which the thickness of the inner layer falls, where that range may be expressed by selecting any of the minimum distances set forth above in combination with any of the maximum distances set forth above, with the maximum distance of course being greater than the minimum distance.

The reactor the present disclosure may be described in terms of the total wall thickness, e.g., from 4 to 8 inches, and the thickness of the inner layer, e.g., ¼ to 1 inch thick, those values and ranges being selected from options provided above. There is no gap between the inner and outer layers of a bilayer reactor, or between any of the adjacent layers of a multi-layer reactor.

In another embodiment, the present disclosure provides a hydrochlorination reactor that incorporates or includes hoops. A hoop refers to a ring of material which encircles the reactor and provides mechanical strength to the reactor when it is operated at high temperature and high pressure. Hoops may be spaced along the length of the reactor. For instance, when the reactor has a cylindrical design, and is standing upright for a distance of about 30 feet, and has a diameter of about 9 feet, hoops may be located at a separation of approximately 6 inches, or 8 inches, or 10 inches, or 12 inches, or 14 inches, or 16 inches, or 18 inches, or 20 inches, or 22 inches, or 24 inches, or 26 inches, or 28 inches, or 30 inches, or 32 inches, or 34 inches, or 36 inches along the height of the reactor, for a total of about 20 hoops, depending on the size of the hoops.

Each hoop will encircle the reactor, and accordingly the inner diameter of the hoop will be the same as, or slightly larger than, the outer diameter of the reactor. In optional embodiments, the hoop will extend from the wall for a distance of about 3-18 inches, or 3-12 inches, or 4-10 inches, or 6-8 inches. In optional embodiments, a hoop will extend up the wall for a distance of about 2 inches, or 2½ inches, or 3 inches, or 3½ inches, or 4 inches, or 4½ inches, or 5 inches, or 5½ inches, or 6 inches.

In another optional embodiment, a hoop is 75 to 125 millimeters thick (3-5 inches), or 75-100 millimeters thick (3-4 inches), and 300 to 600 millimeters deep (12-24 inches), or 300 to 400 millimeters deep (12-16 inches).

In cross-section, the hoop may have, for example, a square, rectangular, or circular appearance. Optionally, the hoop may have a “T” shape like an I-beam on one end to stiffen the hoop.

The hoop may be made from the same material that is used to construct the hydrochlorination reactor. Since the hoop will not come into contact with hydrogen chloride, it is not necessary to pay the premium price that is typically associated with metals that have hydrogen chloride resistance. However, the hoops will reach a temperature of approximately equal to the operating temperature of the hydrochlorination reactor, which is on the order of 600 C, and accordingly must demonstrate good strength at this temperature in order to help maintain the integrity of the reactor.

The hoop is preferably metallic, which includes metal alloys. Suitable materials for forming the hoop include: RA253MA steel (Rolled Alloys, Inc., Temperance, Mich.) and Haynes HR-120 alloy (Haynes International Inc., Kokomo, Ind., USA). HR-120 is a metal alloy containing 33Fe^{a}-37Ni-25Cr-3Co*-2.5Mo*-2.5W*-0.7Cb-0.7Mn-0.6Si-0.20N-0.1A1-0.05C-0.0048 (^{a} as balance; * Maximum). RA253MA is also a metal alloy, where RA253MA contains Cr(20-22)-Ni(10-12)-Si(1.4-2.0)-C(0.05-0.1)-Mn(under 0.8)-P(under 0.04)-S(under 0.03)-N(0.2-0.14)-Ce(0.08-0.03)-Fe(balance). Alternatively, a functional equivalent of either of RA253MA or HR-120 may be used to form the loop.

Accordingly, in one embodiment, the present disclosure provides a reactor for hydrochlorination comprising a reactor shell in the form of a cylinder having an interior and an inner diameter and an exterior and an outer diameter and a longitudinal axis. The interior refers to the space within the reactor that is occupied by the reactants and any material that forms a fluidized bed in the reactor. The inner diameter refers to the shortest distance between two opposing inner walls of the reactor, which is typically constant for a cylindrical reactor. The reactor comprises a plurality of hoops disposed along the longitudinal axis, each hoop encircling the exterior of the reactor shell and being adjacent to and in contact with the exterior of the reactor shell when the reactor is operating at elevating temperature and pressure. In this way, the hoops provide mechanical strength to the reactor, where in the absence of the hoops the reactor shell would not be strong enough to maintain its integrity during the hydrochlorination reactor.

In another aspect, the present disclosure provides a hydrochlorination reactor that comprises HR120 steel or equivalent, and does not contain an acid-resistant liner or a plurality of hoops. This quality of steel provides economical access to both hydrogen chloride resistance and high temperature and pressure stability. Accordingly, an acid-resistant liner is not needed to impart good corrosion resistance to the interior of the reactor, and a backing material or plurality of hoops is not needed to provide strength to the reactor walls.

The reactors of the present disclosure can have a larger diameter, and hence a larger capacity, than hydrochlorination reactors in current commercial use. This increase in size provides significant advantages in terms of operating efficiency, reduced capital cost, and reduced heat loss, among other advantages, each as measured as a in terms of units of reactor volume. A hydrochlorination reactor is typically cylindrical in shape, the cylinder having an inside diameter as measured by the distance between opposing inner walls of the shell, and an exterior diameter as measured by the distance between opposing exterior walls of the shell. In various embodiments, the reactors of the present disclosure have an interior diameter in excess of 3 meters, or in excess of 4 meters, or in excess of 5 meters, or in excess of 6 meters, or in excess of 7 meters, or in excess of 8 meters. In various embodiments, the reactors of the present disclosure have an exterior diameter in excess of 3 meters, or in excess of 4 meters, or in excess of 5 meters, or in excess of 6 meters, or in excess of 7 meters, or in excess of 8 meters. In various embodiments, the reactor has an outer diameter of 3-8 meters, or 3-6 meters, or 3.5-5.5 meters, or 4-5 meters.

The hydrochlorination reactors of the present disclosure may be incorporated into a plant for the production of polysilicon. For example, a plant that produces polysilicon by the Siemens process. The plant may contain a chemical vapor deposition (CVD) reactor that manufactures polysilicon and creates an effluent comprising hydrogen, hydrogen chloride, dichlorosilane, trichlorosilane and silicon tetrachloride.

The present disclosure provides the following additional specific and numbered embodiments, which are exemplary only of the embodiments disclosed herein:
1) A reactor for hydrochlorination, comprising a reactor shell in the form of a cylinder, the shell comprising an inner layer in contact with the contents of the reactor, and an outer layer that is adjacent to and in contact with the inner layer but is not in contact with the contents of the reactor, the inner layer comprising a first material having hydrochloric acid resistance and the outer layer comprising a second material having higher tensile strength than the first material.
2) The reactor of embodiment 1 wherein the first material is selected from Incoloy 800H alloy, tantalum, and stainless steel such as 347 stainless steel and 321 stainless steel.
3) The reactor of embodiment 1 or 2 wherein the second material is selected from RA253MA steel or functional equivalent steel and Haynes HR-120 alloy or functional equivalent alloy.
4) A reactor for hydrochlorination comprising a reactor shell in the form of a cylinder having an interior and an inner diameter and an exterior and an outer diameter and a longitudinal axis, and a plurality of hoops disposed along the longitudinal axis, each hoop encircling the exterior of the reactor shell and being adjacent to and in contact with the exterior of the reactor shell when the reactor is operating at elevating temperature and pressure.
5) The reactor of embodiment 4 wherein a hoop is 75 to 125 millimeters thick and 300 to 600 millimeters deep.
6) A reactor for hydrochlorination that comprises an interior, an exterior, and a reactor wall that separates and contacts each of the interior from the exterior, the reactor wall comprising HR120 steel or equivalent such that HR120 steel or equivalent contacts both the interior and the exterior of the reactor.
7) The reactor of any one of embodiments 1-6 comprising a cylindrical design, the cylinder having an inside diameter as measured by the distance between opposing inner walls of the shell, the inner diameter being in excess of 3 meter.
8) The reactor of embodiment 7 wherein the diameter is in excess of 4 meters.
9) The reactor of embodiment 7 wherein the diameter is in excess of 5 meters.
10) The reactor of embodiment 7 wherein the diameter is in excess of 6 meters.
11) The reactor of embodiment 7 wherein the diameter is in excess of 7 meters.
12) The reactor of embodiment 7 wherein the diameter is in excess of 8 meters.
13) The reactor of any one of embodiments 1-6 comprising a cylindrical design, the cylinder having an outer diameter as measured by the distance between opposing exterior walls of the shell, the outer diameter being in excess of 3 meter.
14) The reactor of embodiment 13 wherein the diameter is in excess of 4 meters.
15) The reactor of embodiment 13 wherein the diameter is in excess of 5 meters.
16) The reactor of embodiment 13 wherein the diameter is in excess of 6 meters.
17) The reactor of embodiment 13 wherein the diameter is in excess of 7 meters.
18) The reactor of embodiment 13 wherein the diameter is in excess of 8 meters.
19) A chemical plant comprising a reactor of any of embodiments 1-18 and a chemical vapor deposition reactor for the production of polysilicon.

Any of the various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A reactor for hydrochlorination, comprising a reactor shell in the form of a cylinder, the shell having a multi-layer construction comprising an inner layer in contact with the contents of the reactor, and an outer layer that is adjacent to and in contact with the inner layer but is not in contact with the contents of the reactor, the inner layer comprising a first material having hydrochloric acid resistance that is greater than or equal to a hydrochloride resistance of the outer layer, and the outer layer comprising a second material having a tensile strength that is greater than or equal to a tensile strength of the first material.

2. The reactor of claim 1 wherein the first material is selected from INCOLOY 800H alloy and tantalum.

3. The reactor of claim 1 wherein the second material is selected from INCOLOY 800 H alloy or functional equivalent alloy, RA253MA steel or functional equivalent steel and Haynes HR-120 alloy or functional equivalent alloy, or stainless steel such as 347 stainless steel and 321 stainless steel.

4. A reactor for hydrochlorination comprising a reactor shell in the form of a cylinder having an interior and an inner diameter and an exterior and an outer diameter and a longitudinal axis, and a plurality of hoops disposed along the longitudinal axis, each hoop encircling the exterior of the reactor shell and being adjacent to and in contact with the exterior of the reactor shell when the reactor is operating at elevating temperature and pressure.

5. The reactor of claim 4 wherein a hoop is 3-5 inches thick and 12-24 inches deep.

6. A reactor for hydrochlorination that comprises an interior, an exterior, and a reactor shell that separates the interior from the exterior, the reactor shell comprising HR120 steel or equivalent such that HR120 steel or equivalent contacts both the interior and the exterior of the reactor.

7. The reactor of claim 1, the cylinder having an inside diameter as measured by the distance between opposing inner walls of the shell, the inner diameter being in excess of 3 meters.

8. The reactor of claim 7 wherein the reactor shell comprises at least an inner layer in contact with the contents of the reactor and an outer layer that is in contact with the inner layer but is not in contact with the contents of the reactor, each of the inner and outer layers having a thickness independently selected from the range of 1.5 to 5.0 inches.

9. The reactor of claim 7 wherein the reactor shell has a thickness of greater than 3.5 inches.

10. A reactor for conducting a hydrochlorination reaction, the reactor comprising a reactor shell, the reactor shell being a multi-layer construct comprising:
a) a first layer in contact with an internal cavity of the reactor, the first layer having a nickel content of at least 25 wt % and a chromium content of at least 17 wt % so as to have hydrochloric acid corrosion resistance;
b) a second layer in contact with the first layer and not in contact with the internal cavity, the second layer having a tensile strength of at least 9,000 psi at 1100° F.

11. The reactor of claim 10 wherein the internal cavity has a minimum diameter of 10-20 feet.

12. The reactor of claim 10 wherein each of the first layer and the second layer has a thickness independently selected from the range of from 0.25-5 inches.

13. The reactor of claim 10 wherein each of the first layer and the second layer has a thickness independently selected from the range of from 1.5-5 inches.

14. The reactor of claim 10 wherein the first and second layers are made from materials having different chemical composition.

15. The reactor of claim 10 wherein the first and second layers are made from materials having identical chemical composition.

16. The reactor of claim 10 wherein the reactor wall further comprises a third layer in contact with the second layer, the third layer not in contact with the first layer.

17. The reactor of claim 10 wherein the second layer entirely encompasses the first layer.

18. A chemical plant comprising a reactor of claim 1 and a chemical vapor deposition reactor for the production of polysilicon.

19. A process for hydrochlorination comprising:
a) providing a hydrochlorination reactor at a temperature in excess of 500° C. and a pressure in excess of 30 barg, the reactor having an inside diameter of between 8 and 20 feet;
b) introducing silicon tetrachloride, hydrogen (H₂) and metallurgical silicon into the hydrochlorination reactor; and
c) collecting trichlorosilane from the hydrochlorination reactor.

20. A process for manufacturing a reactor for conducting a hydrochlorination reaction, the reactor comprising a reactor shell, the reactor shell being a multi-layer construct comprising a first layer in contact with an internal cavity of the reactor and a second layer in contact with the first layer and not in contact with the internal cavity, the process comprising
a) providing a reactor inner layer having an inner diameter and an outer diameter;
b) providing a reactor outer layer having an inner diameter and an outer diameter, where the outer diameter of the inner layer is greater than the inner diameter of the outer layer at room temperature of about 25° C.;
c) heating the outer layer to provide an expanded outer layer, where the expanded outer layer has an inner diameter which is larger than the outer diameter of the inner layer;
d) inserting the inner layer into the expanded outer layer, or slipping the expanded outer layer over the inner layer; and
e) cooling the expanded outer layer to the same temperature of the inner layer to provide a wall of a reactor.
